(19) United States
(12) Patent Application Publication
(10) Pub. No.: US 2007/0045724 A1
(43) Pub. Date: Mar. 1, 2007

(54) Gate pattern of semiconductor device and method for fabricating the same

(75) Inventors: Kwan-Yong Lim, Kyoungki-do (KR); Yun-Seok Chun, Kyoungki-do (KR); Hyun-Jung Kim, Kyoungki-do (KR); Min-Gyu Sung, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/361,378

(22) Filed: Feb. 24, 2006

(30) Foreign Application Priority Data
Aug. 25, 2005 (KR) 2005-0078287

(51) Int. Cl. H01L 29/94

(52) U.S. Cl. 257/330

(57) ABSTRACT

A gate pattern of a semiconductor device and a method for fabricating the same are provided. The gate pattern includes a substrate with a trench, a gate insulation layer, a first gate electrode layer and a second gate electrode layer. The gate insulation layer is formed over the substrate with the trench. The first gate electrode layer is buried into the trench not to be projected above the gate insulation layer. The second gate electrode layer is formed over the first gate electrode layer and has a predetermined portion contacting the first gate electrode layer.

### FIELD OF THE INVENTION

The present invention relates to a gate pattern of a semiconductor device and a method for fabricating the same; and more particularly, to a recess gate pattern of a dynamic random access memory (DRAM) cell transistor having a line width with equal to or less than approximately 100 nm, and a method for fabricating the same. Although the present invention has been applied to a specific memory device, there can be other applications.

### DESCRIPTION OF RELATED ARTS

Recently, as semiconductor device have required low electricity and high capacitance much more, semiconductor device producers have consistently invested in fabricating more highly integrated and speedier semiconductor devices. Accordingly, in order to integrate much more semiconductor devices within a limited semiconductor device chip, a design rule has been continuously reduced.

Particularly, as the scale of integration of a dynamic random access memory (DRAM) device has been rapidly improved, a size of the DRAM device has been continuously reduced and accordingly, a design rule is decreased below 100 nm. However, although a unit device fabrication process is reduced below 100 nm, it is more required to increase an operation speed and improve a capacity of the semiconductor devices such as a low electricity property and a refresh property.

However, as the design rule has been decreased below 100 nm, a line width of a gate pattern is also decreased. Thus, a limitation such as a short-channel effect may be induced. Accordingly, a threshold voltage (Vth) is decreased and a leakage current is increased and thus, a retention time or/and a refresh time may be decreased.

Accordingly, in order to solve the aforementioned limitations, unlike a planar type in which a gate pattern is formed on a substrate plane, a recess gate structure of which a gate insulation layer is formed over an inner surface of a trench formed in a substrate and then, a conductive layer such as polysilicon is filled in the trench is described in this field. The recess gate structure may increase a channel length, thereby increasing the retention time or/and the refresh time.

Meanwhile, to reduce a delay in transferring a signal by a high resistance of a gate pattern, i.e., a word line, the gate pattern may be formed by using a stacked layer (hereinafter, referred to as polycide) of a polysilicon layer and a silicide layer having a very low sheet resistance or a stacked layer (hereinafter, referred to as a polymetal) of a polysilicon layer and a metal layer instead of a single layer made of polysilicon.

FIGS. 1 to 5 are cross-sectional views illustrating a method for fabricating a conventional recess gate pattern including a polymetal gate structure.

First, as shown in FIG. 1, a trench 12 is formed in a predetermined portion of a substrate 10.

Afterwards, as shown in FIG. 2, a gate oxide layer 14 is formed over the substrate 10 including the trench 12 (refer to FIG. 1).

Next, as shown in FIG. 3, a polysilicon layer 16 is deposited as a first gate electrode layer over the gate oxide layer 14 to fill the trench 12 (refer to FIG. 1).

Next, as shown in FIG. 4, a metal layer 18 is formed as a second gate electrode layer over the polysilicon layer 16 and then, a hard mask 20 is deposited over the metal layer 18.

Next, as shown in FIG. 5, a predetermined photoresist pattern (not shown) is formed over the hard mask 20 (refer to FIG. 4) and afterwards, the hard mask 20 is etched by using the photoresist pattern (not shown). As a result, a hard mask pattern 20A is formed.

Next, an etching process is performed by using the hard mask pattern 20A, thereby sequentially etching the metal layer 18 and the polysilicon layer 16. Herein, reference numerals 18A and 16A denote a patterned metal layer and a patterned polysilicon layer, respectively. Accordingly, a recess gate pattern 22 is formed in a type of which a predetermined portion is projected above the gate oxide layer 14 disposed over the substrate 10 in which the trench 12 is not formed. Typically, a height of the patterned polysilicon layer 16 projected over the substrate 10 in which the trench 12 is formed ranges from approximately 500 Å to approximately 800 Å.

However, in case that the gate pattern is formed by using polycide or polymetal, resistance-capacitance may be delayed since the gate pattern has a very high sheet resistance (Rs) as a line width of the gate pattern is reduced.

As a result, to reduce the sheet resistance (Rs), it is required to increase a height of the gate pattern.

FIG. 6 is a micrographic image of scanning electron microscopy (SEM) illustrating a stack structure of a conventional gate pattern having a high aspect ratio.

If the height of the gate pattern is increased under a situation in which the line width of the gate pattern is decreased due to the improved integration, an aspect ratio of the gate pattern may be more increased as shown in FIG. 6. Furthermore, recently, due to the improved integration, not only the line width of the gate pattern is reduced, but also, a distance between the gate patterns is decreased. Accordingly, a gap-fill property of an inter-layer insulation layer deposited between the gate patterns may be degraded, or a gap-fill property of a plug material during forming a landing plug making a substrate to a subsequent contact plug may be degraded. If gate spacers are formed on sidewalls of the gate patterns are formed through a subsequent process, the aforementioned limitations may become more serious.

As a result, to improve the gap-fill property of the inter-layer insulation layer, a method for forming the inter-layer insulation layer after the spacers are formed on the sidewalls of the gate patterns and a landing plug is formed in a predetermined thickness by using a selective epitaxial growth (SEG) process can be suggested. However, the SEG process provides a high thermal budget and a low productivity and thus, the aforementioned method is not suitable to improve the gap-fill property.

Furthermore, another method reducing the height of the gate pattern by forming a metal layer instead of fabricating the gate pattern in a dual stacked structure such as polycide or polymetal can be suggested. However, this method is not suitable because a reliability of a gate oxide layer is degraded. That is, in case of forming the gate pattern (hereinafter, referred to -as a metal gate pattern) by only using the metal layer, an impurity such as carbon (C), chlorine (Cl), and fluorine (F) included in a precursor used during depositing the metal layer or a metal composition is penetrated into the gate oxide layer and thus, the penetrated impurity may degrade the reliability of the gate oxide layer. Furthermore, a silicide reaction may be occurred at an interface between the metal gate pattern and the gate oxide layer. This silicide reaction can also become a factor degrading the reliability of the gate oxide layer.

### SUMMARY OF THE INVENTION

It is, therefore, an object of the present invention to provide a gate pattern of a semiconductor device capable of solving a limitation which a gap-fill property of an inter-layer insulation layer buried between gate patterns is degraded as a line width of a gate pattern and a distance between gate patterns is decreased, and a method for fabricating the same.

Furthermore, it is another object of the present invention to provide a gate pattern of a semiconductor device capable of solving a limitation in which a gap-fill property of a material forming a landing plug making a substrate connected to a subsequent contact plug is degraded as a line width of a gate pattern and a distance between gate patterns are deceased, and a method for fabricating the same.

In accordance with one aspect of the present invention, there is provided a gate pattern of a semiconductor device, including: a substrate with a trench; a gate insulation layer formed over the substrate with the trench; a first gate electrode layer buried into the trench not to be projected above the gate insulation layer disposed over the substrate where the trench is not formed; and a second gate electrode layer formed over the first gate electrode layer and having a predetermined portion contacting the first gate electrode layer.

In accordance with another aspect of the present invention, there is provided a method for fabricating a gate pattern of a semiconductor device, including: preparing a substrate including a trench; forming a gate insulation layer over the substrate including the trench; forming a first gate electrode layer buried into the trench not to be projected above the gate insulation layer disposed over the substrate where the trench is not formed; and forming a second gate electrode layer over the first gate electrode layer to make a predetermined portion of the second gate electrode layer contacting the first gate electrode layer.

### BRIEF DESCRIPTION OF THE DRAWINGS

The above and other objects and features of the present invention will become better understood with respect to the following description of the preferred embodiments given in conjunction with the accompanying drawings, in which:

FIGS. 1 to 5 are cross-sectional views illustrating a method for fabricating a conventional recess gate pattern including a polymetal gate structure;

FIG. 6 is a micrographic image of scanning electron microscopy (SEM) illustrating a stack structure of a conventional gate pattern having a high aspect ratio;

FIG. 7 is a cross-sectional view illustrating a gate pattern of a semiconductor device formed in accordance with a first embodiment of the present invention;

FIGS. 8 to 13 are cross-sectional views illustrating a method for fabricating a gate pattern of a semiconductor device illustrated in FIG. 7; and

FIG. 14 is a cross-sectional view illustrating a gate pattern of a semiconductor device formed in accordance with a second embodiment of the present invention.

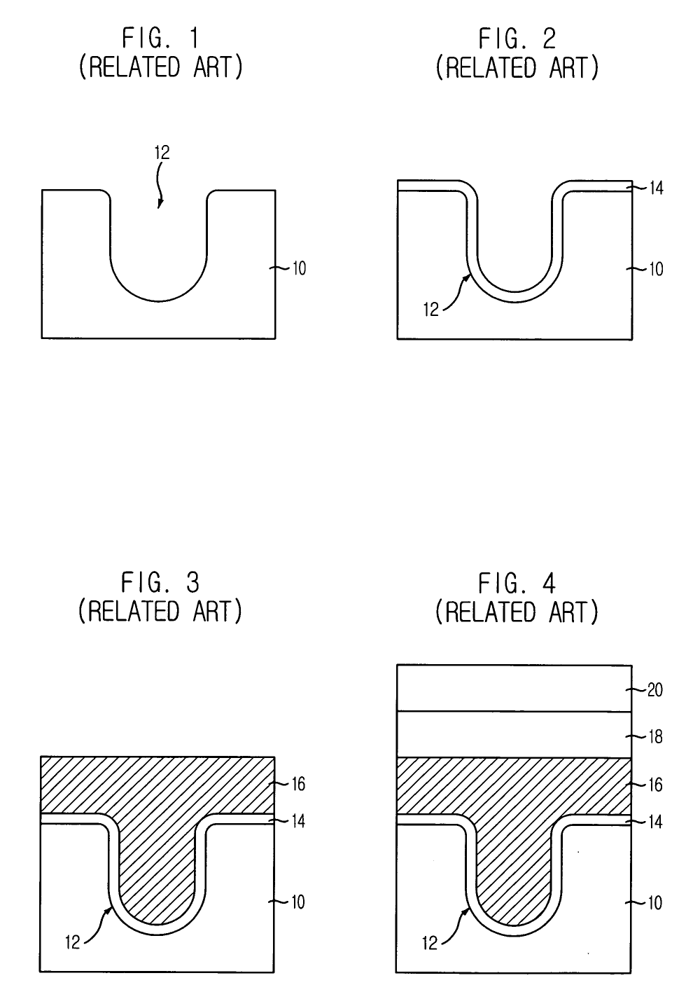

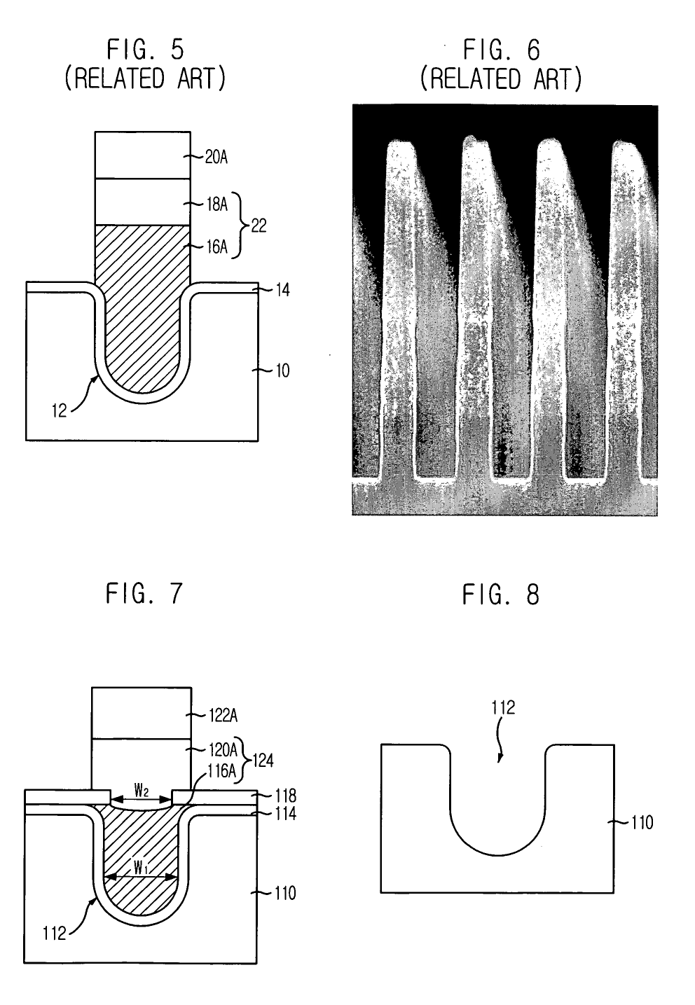

### DETAILED DESCRIPTION OF THE INVENTION

Hereinafter, detailed descriptions on certain embodiments of the present invention will be provided with reference to the accompanying drawings.

Furthermore, thicknesses of layer and regions may be exaggerated to clearly explain them in the drawings. If it is described that a layer is formed over a substrate or a different layer, the layer can be directly formed over the other layer or on a substrate, or another layer can be interposed between the other layer and the substrate. Also, identical reference numerals throughout this specification denote the same constitution elements.

FIG. 7 is a cross-sectional view illustrating a gate pattern of a semiconductor device formed in accordance with a first embodiment of the present invention.

As shown in FIG. 7, the gate pattern of the semiconductor device in accordance with the first embodiment of the present invention includes a substrate 110 provided with a trench 112; a gate insulation layer 114 formed over an upper portion of the substrate 110 including the trench 112; a first gate electrode layer 116A buried into the trench 112 not to be projected over an upper portion of the gate insulation layer 114 disposed over the substrate 110 where the trench 112 is not formed; and a second gate electrode layer 120A formed over the first gate electrode layer 116A to make a predetermined portion of the second gate electrode layer 120A contact the first gate electrode layer 116A and forming a gate pattern 124 along with the first gate electrode layer 116A. In addition, a plurality of etch stop layers 118 formed over the gate insulation layer 114 disposed over the substrate 110 where the trench is not formed and a hard mask 122A formed over the second gate electrode layer 120A may be further included.

Herein, the first gate electrode layer 116A is formed by using poly-SiₓGe₁₋ₓ (herein, x representing an atomic ratio ranges from approximately 0.01 to approximately 0.99), and the second gate electrode layer 120A is formed by using one of a metal layer and a silicide layer. For instance, the second gate electrode layer 120A can be formed by using one selected from the group consisting of WSiₓ, TiSiₓ, NiSiₓ, CoSiₓ, TaSiₓ, MoSiₓ, HfSiₓ, ZrSiₓ, PtSiₓ, W/WN, W/W—Si—N/WSiₓ, W/TiN/TiSiₓ, W/Ti—Si—N/TiSiₓ, Ti—Si—N, Ti—Al—N, Ta—Si—N, MoN, HfN, TaN and TiN (herein, x representing an atomic ratio ranges from approximately 1.0 to approximately 3.0).

At this time, a width W₂ which the first gate electrode layer 116A contacts the second gate electrode layers 120A is smaller than a width W₁ of the first gate electrode layer 116A by a size ranging from approximately 5 nm to approximately 10 nm.

Each of the etch stop layers 118 can be formed over the gate insulation layer disposed over the substrate 110 where the trench 112 is not formed and extend over a portion of the first gate electrode layer 116A not contacting the second gate electrode layer 120A.

The etch stop layers 118 are formed by using a material selected from the group consisting of an oxide-based material, a nitride-based material and a combination thereof. For instance, the oxide-based material can be formed by using one selected from the group consisting of SiO₂, SiOₓN_{y}, HfO₂, HfSiₓO_{y} and HfSiₓO_{y}N_{z} (herein, x, y, and z representing atomic ratios range from approximately 0.1 to approximately 3.0), and the nitride-based material is formed by using silicon nitride (Si₃N₄).

The gate insulation layer 114 is formed by using one selected from the group consisting of SiO₂, SiOₓN_{y}, HfO₂, HfSiₓO_{y} and HfSiₓO_{y}N_{z} (herein, x, y, and z representing atomic ratios range from approximately 0.1 to approximately 3.0).

FIGS. 8 to 13 are cross-sectional views illustrating a method for forming the gate pattern of the semiconductor device shown in FIG. 7.

First, as shown in FIG. 8, a trench 112 is formed in a predetermined portion of a substrate 110. At this time, the substrate 110 can be one selected from the group consisting of a silicon (Si) substrate, a silicon geranium (SiGe) substrate, a strained-Si substrate, a silicon-on-insulator (SOI) substrate and a germanium-on-insulator (GOI) substrate.

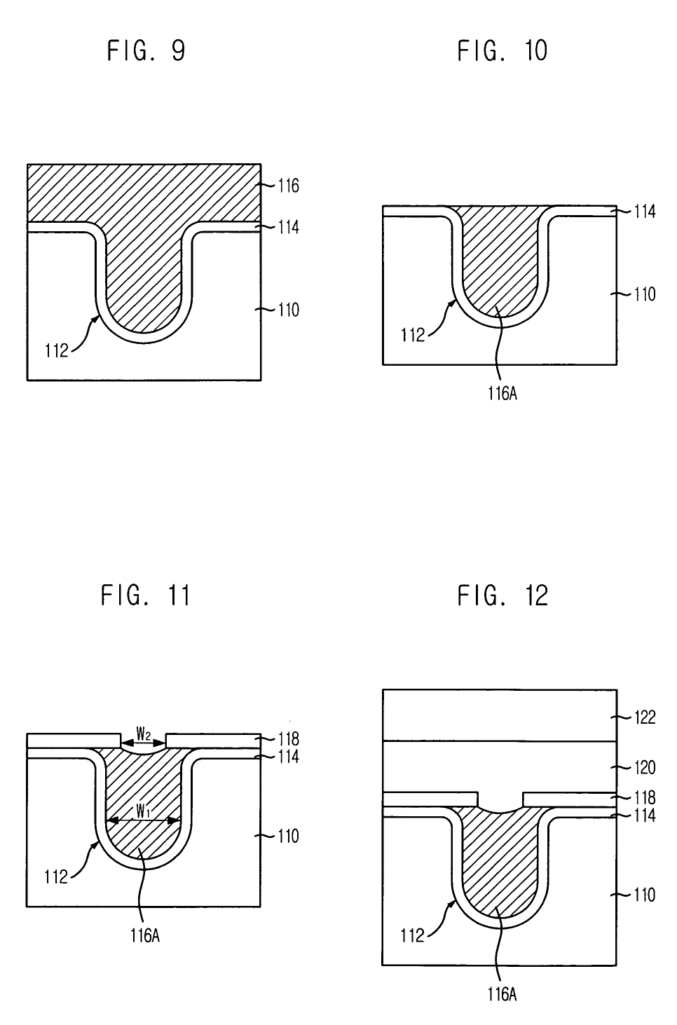

Next, as shown in FIG. 9, an oxidation process is performed, thereby forming a gate oxide layer 114 as a gate insulation layer over the substrate 110 including the trench 112 (refer to FIG. 8). At this time, the oxidation process can be performed in a wet oxidation method which heats the substrate 110 in oxidized gas such as vapor at a temperature ranging from approximately 900° C. to approximately 1,000° C. or in a dry oxidation method which heats the substrate 110 by using pure oxygen as oxidized gas at a temperature of approximately 1,200° C. Through the oxidation process, the gate oxide layer 114 can be formed by using a material selected from the group consisting of SiO₂, SiOₓN_{y}, HfO₂, HfSiₓO_{y} and HfSiₓO_{y}N_{z} (herein, x, y, and z representing atomic ratios range from approximately 0.1 to approximately 3.0).

Next, a first gate electrode layer 116 such as a poly-crystal silicon layer in which an impurity is doped over the gate oxide layer 114 is deposited to fill the trench 112 (refer to FIG. 8). For instance, to form the first gate electrode layer 116, polysilicon or poly-SiₓGe₁₋ₓ (herein, x ranges from approximately 0.01 to approximately 0.99) is deposited through a low pressure chemical vapor deposition (LPCVD) method. The aforementioned polysilicon or poly-SiₓGe₁₋ₓ can be deposited through the LPCVD method using a gas mixture obtained by mixing one of phosphine (PH₃), PCl₅, boron trichloride (BCl₃) and diborane (B₂H₆) into silane (SiH₄).

Next, as shown in FIG. 10, an etch-back process or a chemical mechanical polishing (CMP) process is performed not to make the first gate electrode layer 116 projected over an upper portion of the gate oxide layer 114 disposed over the substrate where the trench 112 is not formed (refer to FIG. 8) thereby planarizing the first gate electrode layer 116. Herein, the planarized gate electrode layer is denoted as a reference numeral 116A. For instance, in case of performing the etch-back process, the gate oxide layer 114 disposed over the substrate 110 where the trench 112 is not formed is used as an etch stop layer. Furthermore, in case of performing the CMP process, the gate oxide layer 114 disposed over the substrate 110 where the trench 112 is not formed is used as a planarization stop layer.

Next, as shown in FIG. 11, an etch stop layer 118 is deposited over the above resulting structure including the planarized first gate electrode layer 116A. At this time, the etch stop layer 118 is deposited in a thickness ranging from approximately 30 Å to approximately 300 Å to prevent the gate oxide layer 114 from being degraded during subsequent processes including a photolithography process, an etching process or a cleaning process. For instance, the etch stop layer 118 is formed by using a material selected from the group consisting of an oxide-based material, a nitride-based material and a combination thereof. The oxide-based material can be formed by using one selected from the group consisting of SiO₂, SiOₓN_{y}, HfO₂, HfSiₓO_{y} and HfSiₓO_{y}N_{z}, and the nitride-based material can be formed by using Si₃N₄.

Next, a photoresist layer (not shown) is deposited over the etch stop layer 118 and then, a photo-exposure process and a developing process using a photomask (not shown) are performed, thereby forming a photoresist pattern (not shown). Afterwards, a predetermined portion of the etch stop layer 118 is etched through an etching process using the photoresist pattern as an etch mask. Accordingly, a predetermined portion of the planarized first gate electrode layer 116A is exposed.

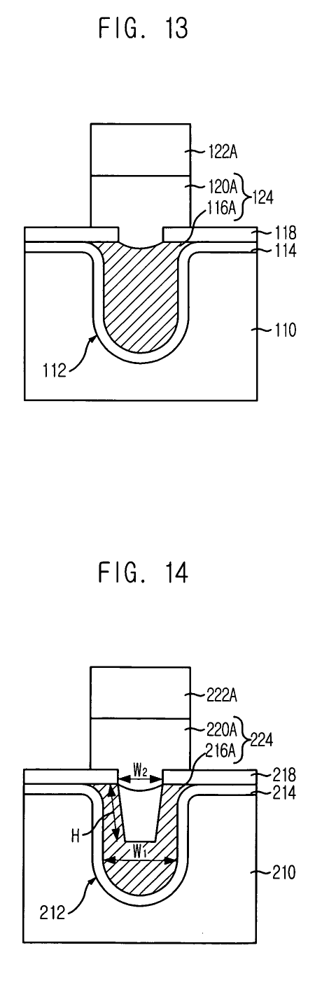

At this time, the exposed portion of the planarized first gate electrode layer 116A is a region supposed to contact a second gate electrode layer 120 (refer to FIG. 12) which will be formed through a subsequent process, and a width (W₂) of the exposed portion of the planarized first gate electrode layer 116A is smaller than a width (W₁) of the planarized first gate electrode layer 116A by a size ranging from approximately 5 nm to approximately 10 nm.

Next, as shown in FIG. 12, a typical stripping process is performed, thereby removing the photoresist pattern (not shown).

Next, the aforementioned second gate electrode layer 120 is deposited over the above resulting structure including the etch stop layer 118. At this time, the second gate electrode layer 120 is formed by using either a metal layer or a silicide layer. For instance, the second gate electrode layer 120 is formed by using one selected from the group consisting of WSiₓ, TiSiₓ, NiSiₓ, CoSiₓ, TaSiₓ, MoSiₓ, HfSiₓ, ZrSiₓ, PtSiₓ, W/WN, W/W—Si—N/WSiₓ, W/TiN/TiSiₓ, W/Ti—Si—N/TiSiₓ, Ti—Si—N, Ti—Al—N, Ta—Si—N, MoN, HfN, TaN, and TiN (herein, x representing an atomic ratio ranges from approximately 1.0 to approximately 3.0). Also, the second gate electrode layer 120 can be formed by using WSiₓ.

Next, a hard mask 122 can be formed over the second gate electrode layer 120. Herein, the hard mask 120 is deposited to use a hard mask scheme during performing a subsequent etching process of the second gate electrode layer 120. The hard mask scheme is a process etching a lower structure by using a hard mask pattern as an etch mask.

Next, as shown in FIG. 13, a photoresist layer (not shown) is deposited over the hard mask 122 (refer to FIG. 12) and then, a photo-exposure process and a developing process using a photomask (not shown) are performed, thereby forming a photoresist pattern (not shown).

Next, a predetermined portion of the second gate electrode layer 120 is etched by using the hard mask scheme. For instance, a hard mask pattern 122A is formed through the etching process using the photoresist pattern as an etch mask and afterwards, the photoresist pattern is removed, thereby etching the second gate electrode layer 120 by using the hard mask pattern 122A as an etch mask. The second gate electrode layer 120 is etched to be overlapped with the planarized first gate electrode layer 116A. Herein, a reference numeral 120A denotes a patterned second gate electrode layer.

Through these steps, a gate pattern with a recess structure comprised by the planarized first gate electrode layer 116A formed inside the trench 112 (refer to FIG. 8) of the substrate 110 and the patterned second electrode layer 120A contacting the predetermined portion of the first gate electrode layer 116A can be formed.

That is, in accordance with the first embodiment of the present invention, it is possible to reduce a height of the gate pattern by making the first gate electrode layer buried into the trench inside the substrate not projected over the substrate in which the trench is not formed. Specifically, polysilicon which is the first gate electrode layer is projected over the substrate in which the trench is not formed by a thickness ranging from approximately 500 Å to approximately 800 Å according to the conventional gate pattern. However, in accordance with the first embodiment of the present invention, the height of the gate pattern is decreased by a size ranging from approximately 500 Å to approximately 800 Å.

Accordingly, it is possible to reduce an aspect ratio of a space between gate electrode layers during forming the gate pattern with the recess structure. Thus, it is possible to improve a gap-fill property of an inter-layer insulation layer buried between the gate electrode layers and a gap-fill property of a landing plug material.

A second embodiment of the present invention of the present invention is characterized in which a planarized first gate electrode layer is recessed to a predetermined thickness ranging from approximately 5 nm to approximately 100 nm, i.e., the predetermined thickness to be recessed is smaller than a depth of a trench, at a contact region between the planarized first gate electrode layer and a second gate electrode layer. Accordingly, the contact area between the planarized first gate electrode layer and the second gate electrode layer is increased by the recessed depth and thus, current flows very well between the planarized first gate electrode layer and the second gate electrode layer. Accordingly, in accordance with the first embodiment of the present invention, a contact resistance inside a gate pattern can be much more reduced. As a result, in accordance with the second embodiment of the present invention, it is possible to obtain an effect in reducing the contact resistance inside a gate pattern in addition to the effect obtained in accordance with the first embodiment of the present invention.

FIG. 14 is a cross-sectional view illustrating a gate pattern of a semiconductor device in accordance with a second embodiment of the present invention.

As shown in FIG. 14, the gate pattern of the semiconductor device includes a substrate 210 provided with a trench 212; a gate insulation layer 214 formed over the substrate 210 including the trench 212; a first gate electrode layer 216A buried into the trench 212 not to be projected over the gate insulation layer 214 disclosed over the substrate 210 where the trench 212 is not formed and having a predetermined portion recessed to a predecided depth (H); and a second gate electrode layer 220A formed over the recessed first gate electrode layer 216A and forming a gate pattern 224 along with the first gate electrode layer 216A.

The gate pattern of the semiconductor device shown in FIG. 14 in accordance with the second embodiment of the present invention is nearly identical to the processes shown in FIGS. 8 to 11 in accordance with the first embodiment of the present invention. However, only the process recessing a certain portion of the first gate electrode layer 216A to a predecided depth (H) by performing an etching process using an etch stop layer 218 as an etch mask is different from the first embodiment of the present invention. Accordingly, explanations about the identical processes performed before the above recessing process will be omitted.

As described above, in accordance with the present invention, it is possible to reduce a general height of a gate pattern by making a first gate electrode layer buried into a trench inside a substrate not to be projected over an upper portion of the substrate in which the trench is not formed. Accordingly, during forming a gate pattern with a recess structure, it is possible to reduce an aspect ratio of a space between gate patterns. Due to the reduced aspect ratio, it is also possible to improve a gap-fill property of an inter-layer insulation layer buried between the gate patterns and a gap-fill property of a landing plug material.

Furthermore, as a height of the gate pattern is decreased, a parasitic capacitance generated by an overlap between a gate pattern and a source/drain contact plug or between gate patterns can be reduced. Accordingly, it is possible to obtain not only an effect in reducing a delay of resistance-capacitance but also an effect in improving a sensing margin and a retention property in case of a DRAM device.

The present application contains subject matter related to the Korean patent application No. KR 2005-0078287, filed in the Korean Patent Office on Aug. 25, 2005 the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A gate pattern of a semiconductor device, comprising:
a substrate with a trench;
a gate insulation layer formed over the substrate with the trench;
a first gate electrode layer buried into the trench not to be projected above the gate insulation layer disposed over the substrate where the trench is not formed; and
a second gate electrode layer formed over the first gate electrode layer and having a predetermined portion contacting the first gate electrode layer.

2. The gate pattern of claim 1, wherein the first gate electrode layer is recessed to a predetermined depth at a contact region between the first gate electrode layer and the second gate electrode layer, so that the first gate electrode layer contacts the second gate electrode layer.

3. The gate pattern of claim 2, wherein a width of the contact region between the first gate electrode layer and the second gate electrode layer is smaller than that of the first gate electrode layer by a size ranging from approximately 5 nm to approximately 10 nm.

4. The gate pattern of claim 3, wherein the first gate electrode layer includes one of polysilicon and poly-SiₓGe₁₋ₓ, where x representing an atomic ratio ranges from approximately 0.01 to approximately 0.99.

5. The gate pattern of claim 1, wherein the second gate electrode layer includes one of a metal layer and a silicide layer.

6. The gate pattern of claim 5, wherein the second gate electrode layer includes one selected from the group consisting of WSiₓ, TiSiₓ, NiSiₓ, CoSiₓ, TaSiₓ, MoSiₓ, HfSiₓ, ZrSiₓ, PtSiₓ, W/WN, W/W—Si—N/WSiₓ, W/TiN/TiSiₓ, W/Ti—Si—N/TiSiₓ, Ti—Si—N, Ti—Al—N, Ta—Si—N, MoN, HfN, TaN and TiN, where x representing an atomic ratio ranges from approximately 1.0 to approximately 3.0.

7. The gate pattern of claim 1, further comprising an etch stop layer formed over the gate insulation layer disposed over the substrate where the trench is not formed and extending over a portion of the first gate electrode layer not contacting the second gate electrode layer.

8. The gate pattern of claim 7, wherein the etch stop layer includes one selected from the group consisting of an oxide-based material, a nitride-based material and a combination thereof.

9. The gate pattern of claim 8, wherein the oxide-based material is one selected from the group consisting of SiO₂, SiOₓN_{y}, HfO₂, HfSiₓO_{y} and HfSiₓO_{y}N_{z}, where x, y and z representing atomic ratios range from approximately 0.1 to approximately 3.0, and the nitride-based material includes silicon nitride (Si₃N₄).

10. The gate pattern of claim 7, wherein the gate insulation layer includes one selected from the group consisting of SiO₂, SiOₓN_{y}, HfO₂, HfSiₓO_{y} and HfSiₓO_{y}N_{z}, wherein x, y and z representing atomic ratios range from approximately 0.1 to approximately 3.0.

11. The gate pattern of claim 7, further comprising a hard mask formed over the second gate electrode layer.

12. A method for fabricating a gate pattern of a semiconductor device, comprising:
preparing a substrate including a trench;
forming a gate insulation layer over the substrate including the trench;
forming a first gate electrode layer buried into the trench not to be projected above the gate insulation layer disposed over the substrate where the trench is not formed; and
forming a second gate electrode layer over the first gate electrode layer to make a predetermined portion of the second gate electrode layer contacting the first gate electrode layer.

13. The method of claim 12, wherein the forming of the first gate electrode layer buried into the trench includes:
forming a first gate electrode layer over the gate insulation layer to fill the trench; and
etching the first gate electrode layer through one of an etch-back process and a chemical mechanical polishing (CMP) process up to an upper portion of the gate insulation layer disposed over the substrate in which the trench is not formed.

14. The method of claim 13, after the etching of the first gate electrode layer up to the upper portion of the gate insulation layer disposed over the substrate where the trench is not formed, further including recessing a portion of the first gate electrode layer corresponding to a contact region in which the first gate electrode layer contacts the second gate electrode layer to a predetermined depth.

15. The method of claim 14, wherein the contact region has a width smaller than the first gate electrode layer by a size ranging from approximately 5 nm to approximately 10 nm.

16. The method of claim 12, after the forming of the first gate electrode layer, further including:
forming an etch stop layer over the first gate electrode layer and the gate insulation layer; and
exposing a predetermined portion of the first gate electrode layer by etching a predecided portion of the etch stop layer.

17. The method of claim 16, wherein the etch stop layer includes one selected from the group consisting of an oxide-based material, a nitride-based material and a combination thereof.

18. The method of claim 17, where the oxide-based material is one selected from the group consisting of SiO₂, SiOₓNy_{y}, HfO₂, HfSiₓO_{y} and HfSiₓO_{y}N_{z}, wherein x, y and z representing atomic ratios range from approximately 0.1 to approximately 3.0, and the nitride-based material is formed by using Si₃N₄.

19. The method of claim 18, wherein the first gate electrode layer includes one of polysilicon and poly-SiₓGe₁₋ₓ, where x representing an atomic ratio ranges from approximately 0.01 to approximately 0.99.

20. The method of claim 12, wherein the second gate electrode layer includes one of a metal layer and a silicide layer.

21. The method of claim 20, wherein the second gate electrode layer includes one selected from the group consisting of WSiₓ, TiSiₓ, NiSiₓ, CoSiₓ, TaSiₓ, MoSiₓ, HfSiₓ, ZrSiₓ, PtSiₓ, W/WN, W/W—Si—N/WSiₓ, W/TiN/TiSiₓ, W/Ti—Si—N/TiSiₓ, Ti—Si—N, Ti—Al—N, Ta—Si—N, MoN, HfN, TaN and TiN, where x representing an atomic ratio ranges from approximately 1.0 to approximately 3.0.

22. The method of claim 21, wherein the forming of the second gate electrode layer includes:
forming the second gate electrode layer over the first gate electrode layer and the etch stop layer; and
etching a predetermined portion of the second gate electrode layer.

23. The method of claim 22, wherein the etching of the predetermined portion of the second gate electrode layer uses a hard mask scheme.

24. The method of claim 21, wherein the gate insulation layer includes one selected from the group consisting of SiO₂, SiOₓN_{y}, HfO₂, HfSiₓO_{y} and HfSiₓO_{y}N_{z}, where x, y and z representing atomic ratios range from approximately 0.1 to approximately 3.0.
